(19) United States
(12) Patent Application Publication
(10) Pub. No.: US 2010/0104754 A1
(43) Pub. Date: Apr. 29, 2010

(54) MULTIPLE GAS FEED APPARATUS AND METHOD

(75) Inventors: ALAN TSO, San Jose, CA (US); Lun Tsuei, Mountain View, CA (US); Tom K. Cho, Los Altos, CA (US); Brian Sy-Yuan Shieh, Palo Alto, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/582,163

(22) Filed: Oct. 20, 2009

Related U.S. Application Data
(60) Provisional application No. 61/108,415, filed on Oct. 24, 2008.

(51) Int. Cl. C23C 16/455; C23C 16/00

(52) U.S. Cl. 427/255.23; 118/715

(57) ABSTRACT

Embodiments of the present invention generally provide apparatus and methods for introducing process gases into a processing chamber at a plurality of locations. In one embodiment, a central region of a showerhead and corner regions of a showerhead are fed process gases from a central gas source with a first mass flow controller regulating the flow in the central region and a second mass flow controller regulating the flow in the corner regions. In another embodiment, a central region of a showerhead is fed process gases from a first gas source and corner regions of the showerhead are fed process gases from a second gas source. In another embodiment, a central region of a showerhead is fed process gases from a first gas source and each corner region of the showerhead is fed process gases from a separate gas source. By separately feeding process gases to different regions of the showerhead, the ratio and flow of process gases through the showerhead may be controlled to provide improved uniformity across the surface of a substrate.

### CROSS-REFERENCE TO RELATED APPLICATIONS

This application claims benefit of U.S. provisional patent application Ser. No. 61/108,415, filed Oct. 28, 2008, which is herein incorporated by reference.

### BACKGROUND OF THE INVENTION

1. Field of the Invention

Embodiments of the present invention provide apparatus and methods for feeding process gas to multiple locations on a substrate.

2. Description of the Related Art

As demand for larger solar panels and flat panel displays continues to increase, so must the size of substrates and chambers for processing the substrates. One method for depositing material onto a substrate for solar panels or flat panel displays is plasma enhanced chemical vapor deposition (PECVD). In PECVD, process gases are typically introduced across a showerhead in a process chamber through a central gas feed orifice. The process gases diffuse through the showerhead and are ignited into plasma by an RF current applied to the showerhead. The plasma envelops a substrate disposed in a process region of the chamber and deposits thin films on the surface of a substrate.

As substrate sizes increase, the uniformity of the films deposited on the substrate becomes increasingly difficult. Therefore, there is a need in the art for an apparatus and method for improved uniformity of process gases across the surface of a showerhead.

### SUMMARY OF THE INVENTION

In one embodiment of the present invention, a processing apparatus comprises a showerhead, a backing plate positioned adjacent the showerhead such that a plenum is formed between the backing plate and the showerhead, a first gas source in fluid communication with an orifice formed through a central region of the backing plate, and a second gas source in fluid communication with an orifice formed through a corner region of the backing plate.

In another embodiment, a processing apparatus comprises a showerhead, a backing plate positioned adjacent the showerhead such that a plenum is formed between the backing plate and the showerhead, wherein the plenum includes a central region and a plurality of corner regions, a first gas source in fluid communication with the central region of the plenum, a first mass flow controller in fluid communication with the first gas source and the central region of the plenum, a second gas source in fluid communication with at least one corner region of the plenum, and a second mass flow controller in fluid communication with the second gas source and the at least one corner region of the plenum.

In another embodiment, a processing apparatus comprises a showerhead, a backing plate juxtaposed the showerhead such that a plenum is formed between the backing plate and the showerhead, wherein the plenum includes a central region and a plurality of corner regions, a gas source in fluid communication with the central and corner regions of the plenum, a first mass flow controller in fluid communication with the gas source and the central region of the plenum, and a second mass flow controller in fluid communication with the gas source and at least one of the corner regions of the plenum.

In yet another embodiment, a method for depositing thin films comprises introducing a first gas mixture into a central region of a plenum formed between a backing plate and a showerhead of a processing apparatus, introducing a second gas mixture into a corner region of the plenum, and substantially preventing the first gas mixture from mixing with the second gas mixture prior to diffusing through the showerhead.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a simplified schematic diagram of a single junction amorphous or micro-crystalline silicon solar cell that can be formed using embodiments of the present invention.

FIG. 1B is a schematic diagram of an embodiment of a solar cell, which is a multi-junction solar cell that is oriented toward the light or solar radiation.

FIG. 2 is a schematic, cross-sectional view of a process chamber, which may be utilized according to one embodiment of the present invention.

FIG. 3 is a schematic, isometric view of a backing plate of a process chamber according to one embodiment of the present invention.

FIG. 4 is a schematic, isometric view of a backing plate of a process chamber according to another embodiment of the present invention.

FIG. 5 is a schematic, isometric view of a backing plate of a process chamber according to another embodiment of the present invention.

FIG. 6 is a schematic, bottom view of a backing plate according to one embodiment of the present invention.

### DETAILED DESCRIPTION

Embodiments of the present invention generally provide apparatus and methods for introducing process gases into a processing chamber at a plurality of locations. In one embodiment, a central region of a showerhead and corner regions of a showerhead are fed process gases from a central gas source with a first mass flow controller regulating the flow in the central region and a second mass flow controller regulating the flow in the corner regions. In another embodiment, a central region of a showerhead is fed process gases from a first gas source and corner regions of the showerhead are fed process gases from a second gas source. In another embodiment, a central region of a showerhead is fed process gases from a first gas source and each corner region of the showerhead is fed process gases from a separate gas source. By separately feeding process gases to different regions of the showerhead, the ratio and flow of process gases through the showerhead may be controlled to provide improved uniformity across the surface of a substrate. Certain embodiments of the present invention may provide significant benefits for depositing microcrystalline silicon films for use in solar cell manufacturing.

The invention is illustratively described below in reference to a chemical vapor deposition system, processing large area substrates, such as a PECVD system, available from Applied Materials, Inc., Santa Clara, Calif. However, it should be understood that the apparatus and method may have utility in other system configurations.

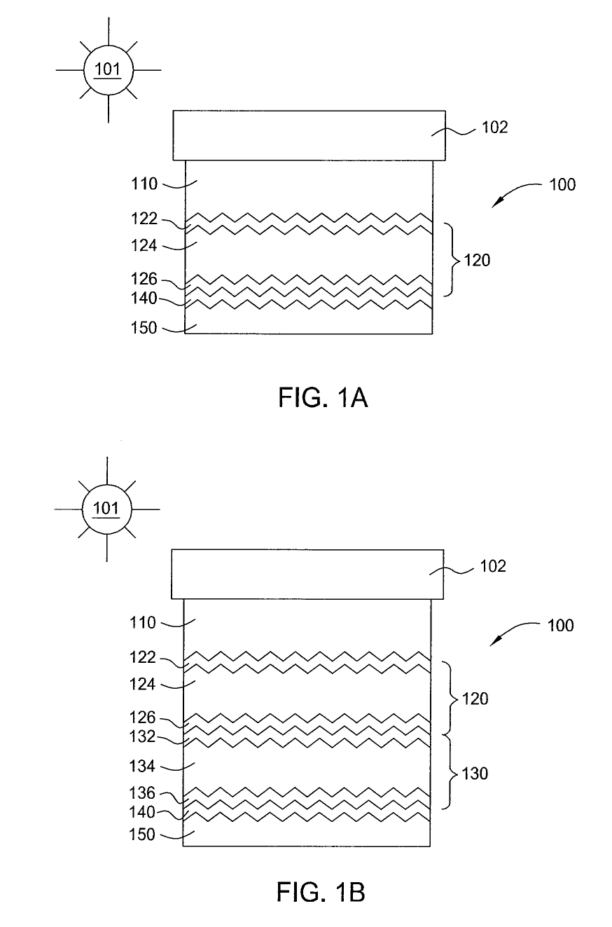

Examples of a solar cell 100 that can be formed using embodiments of the present invention are illustrated in FIGS. 1A-1B. FIG. 1A is a simplified schematic diagram of a single junction solar cell 100 that can be formed using embodiments of the present invention subsequently described. As shown in FIG. 1A, the single junction solar cell 100 is oriented toward a light source or solar radiation 101. The solar cell 100 generally comprises a substrate 102, such as a glass substrate, polymer substrate, metal substrate, or other suitable substrate, with thin films formed thereover. In one embodiment, the substrate 102 is a glass substrate that is about 2200 mm×2600 mm×3 mm in size. The solar cell 100 further comprises a first transparent conducting oxide (TCO) layer 110 (e.g., zinc oxide (ZnO), tin oxide (SnO)) formed over the substrate 102, a first p-i-n junction 120 formed over the first TCO layer 110, a second TCO layer 140 formed over the first p-i-n junction 120, and a back contact layer 150 formed over the second TCO layer 140. To improve light absorption by enhancing light trapping, the substrate and/or one or more of thin films formed thereover may be optionally textured by wet, plasma, ion, and/or mechanical processes. For example, in the embodiment shown in FIG. 1A, the first TCO layer 110 is textured, and the subsequent thin films deposited thereover generally follow the topography of the surface below it. In one configuration, the first p-i-n junction 120 may comprise a p-type amorphous silicon layer 122, an intrinsic type amorphous silicon layer 124 formed over the p-type amorphous silicon layer 122, and an n-type amorphous silicon layer 126 formed over the intrinsic type amorphous silicon layer 124. In one example, the p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type amorphous silicon layer 126 may be formed to a thickness between about 100 Å and about 500 Å. The back contact layer 150 may include, but is not limited to a material selected from the group consisting of Al, Ag, Ti, Cr, Au, Cu, Pt, alloys thereof, and combinations thereof.

FIG. 1B is a schematic diagram of an embodiment of a solar cell 100, which is a multi-junction solar cell that is oriented toward the light or solar radiation 101. Solar cell 100 comprises a substrate 102, such as a glass substrate, polymer substrate, metal substrate, or other suitable substrate, with thin films formed thereover. The solar cell 100 may further comprise a first transparent conducting oxide (TCO) layer 110 formed over the substrate 102, a first p-i-n junction 120 formed over the first TCO layer 110, a second p-i-n junction 130 formed over the first p-i-n junction 120, a second TCO layer 140 formed over the second p-i-n junction 130, and a back contact layer 150 formed over the second TCO layer 140. In the embodiment shown in FIG. 1B, the first TCO layer 110 is textured, and the subsequent thin films deposited thereover generally follow the topography of the surface below it. The first p-i-n junction 120 may comprise a p-type amorphous silicon layer 122, an intrinsic type amorphous silicon layer 124 formed over the p-type amorphous silicon layer 122, and an n-type microcrystalline silicon layer 126 formed over the intrinsic type amorphous silicon layer 124. In one example, the p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type microcrystalline silicon layer 126 may be formed to a thickness between about 100 Å and about 400 Å. The second p-i-n junction 130 may comprise a p-type microcrystalline silicon layer 132, an intrinsic type microcrystalline silicon layer 134 formed over the p-type microcrystalline silicon layer 132, and an n-type amorphous silicon layer 136 formed over the intrinsic type microcrystalline silicon layer 134. In one example, the p-type microcrystalline silicon layer 132 may be formed to a thickness between about 100 Å and about 400 Å, the intrinsic type microcrystalline silicon layer 134 may be formed to a thickness between about 10,000 Å and about 30,000 Å, and the n-type amorphous silicon layer 136 may be formed to a thickness between about 100 Å and about 500 Å. The back contact layer 150 may include, but is not limited to a material selected from the group consisting of Al, Ag, Ti, Cr, Au, Cu, Pt, alloys thereof, and combinations thereof.

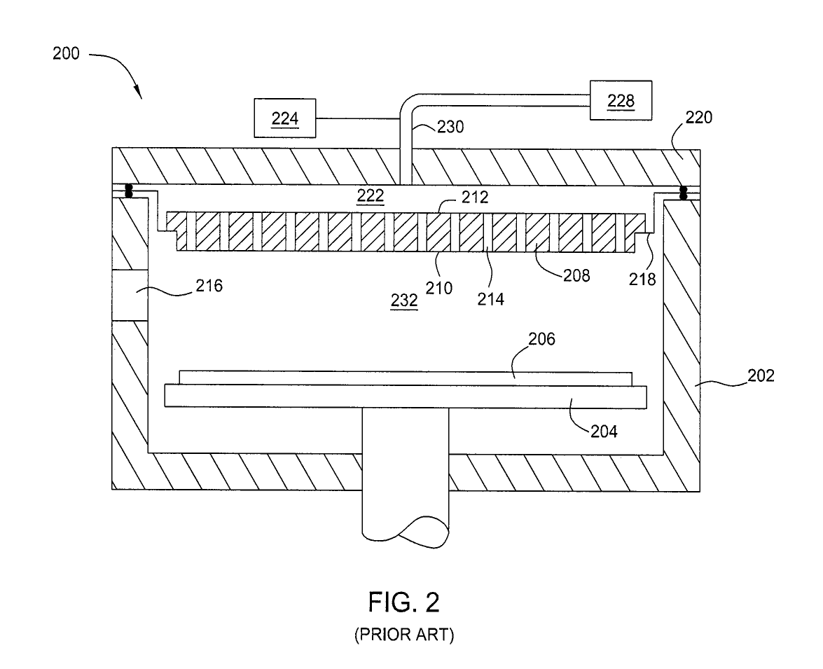

FIG. 2 is a schematic, cross-sectional view of a process chamber 200, which may be utilized according to one embodiment of the present invention. The process chamber 200 includes a chamber body 202 enclosing a susceptor 204 for holding a substrate 206 thereon. The substrate 206 may comprise a glass or polymer substrate such as for solar panel manufacturing, flat panel display manufacturing, organic light emitting display manufacturing, or the like.

The substrate 206 may rest on the susceptor 204 in the chamber body 202 across a processing region 232 from a gas distribution showerhead 208. The substrate 206 may enter and exit the process chamber 200 through a slit valve opening 216 disposed through the chamber body 202.

The gas distribution showerhead 208 may have a downstream surface 210 that faces the processing region 232 and the substrate 206. The gas distribution showerhead 208 may also have an upstream surface 212 disposed opposite the downstream surface 210. A plurality of gas passages 214 extend through the gas distribution showerhead 208 from the upstream surface 212 to the downstream surface 210.

Process gas may be introduced into the process chamber 200 from a first gas source 228. The process gas travels from the first gas source 228 through a central region of the backing plate 220 via a gas tube 230. The gas expends into a plenum 222 formed between the backing plate 220 and the upstream surface 212 of the gas distribution showerhead 208. The process gas then diffuses through the gas distribution showerhead 208 into the processing region 232.

An RF power source 224 may be coupled to the process chamber 200 at the gas tube 230. When RF power is used, the RF current may travel along the backing plate 220, a ledge 218, and the downstream surface 210 of the gas distribution showerhead 208, where it ignites the process gas into plasma in the processing region 232.

Consistent and uniform film deposition over a large area substrate is difficult. In particular, when depositing films over the surface of a large area polygonal substrate, uniformity difficulties in the corner regions typically arise. Therefore, in one embodiment of the present invention, process gas is separately introduced to corner regions of the showerhead 208 through corner regions of the backing plate 220.

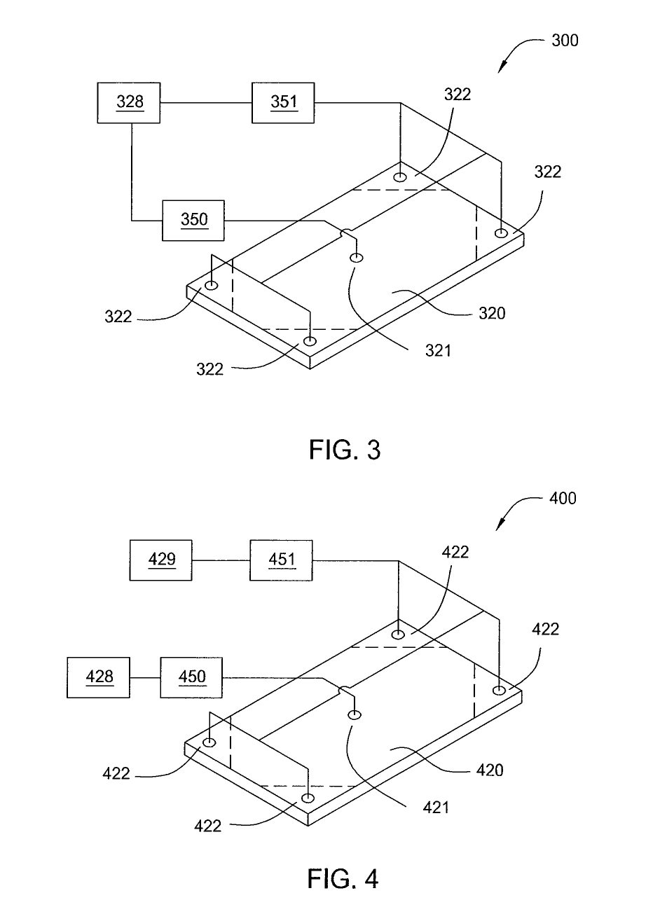

FIG. 3 is a schematic, isometric view of a backing plate 320 of a process chamber 300 according to one embodiment of the present invention. In one embodiment, a gas source 328 may supply process gases to the process chamber 300. The process gas from the gas source 328 may be supplied through a central region 321 of the backing plate 320. The flow of process gas through the central region 321 of the backing plate 320 may be regulated via a mass flow controller 350.

In one embodiment, the process gas from the gas source 328 may be supplied through a plurality of corner regions 322 of the backing plate 320. The flow and/or pressure of process gas through the corner regions 322 of the backing plate 320 may be regulated by one or more mass flow controllers 351. In one embodiment, a single mass flow controller 351 regulates the flow of process gas through the corner regions 322. In another embodiment, the flow of process gas through each corner region 322 is regulated via a separate flow controller 351.

In one embodiment, the process gas may comprise one or more precursor gases. The process gas may be delivered to the central region 321 of the backing plate 320 at a first flow rate. Additionally, the process gas may be delivered to the corner regions 322 at a second flow rate. Therefore, the ratio of the flow rate of process gas delivered to the central region 321 to the flow rate of process gas delivered to the corner regions may be optimized to provide improved deposition uniformity across a substrate disposed in the process chamber 300.

In one embodiment, the process gas may be delivered to each of the corner regions 322 at a different flow rate. Therefore, the ratio of the flow rate of process gas delivered through the central region 321 to the flow rate of process gas delivered through each corner region 322 may be optimized to provide improved deposition uniformity across a substrate disposed in the process chamber 300.

Although the corner regions 322 are depicted as being in the corners of the backing plate 320, one or more corner regions 322 may extend along an edge of the backing plate 320 as well. As such, process gas flow to the edge regions may also be optimized to account for asymmetry in chamber walls, such as slit valve openings.

FIG. 4 is a schematic, isometric view of a backing plate 420 of a process chamber 400 according to one embodiment of the present invention. In one embodiment, process gases may be supplied to the process chamber 400 via a plurality of gas sources. Process gas from a first gas source 428 may be supplied through a central region 421 of the backing plate 420. The flow and/or pressure of process gas through the central region 421 of the backing plate 420 may be regulated via a mass flow controller 450.

In one embodiment, process gas from a second gas source 429 may be supplied through a plurality of corner regions 422 of the backing plate 420. The flow and/or pressure of process gas through the corner regions 422 of the backing plate 420 may be regulated by one or more mass flow controllers 451. In one embodiment, a single mass flow controller 451 regulates the flow and/or pressure of process gas through the corner regions 422. In another embodiment, the flow and/or pressure of process gas through each corner region 422 is regulated via a separate flow controller 451.

In one embodiment, the process gas from the first gas source 428 may comprise one or more precursor gases, and the process gas from the second gas source 429 may comprise one or more precursor gases. In one embodiment, a first process gas mixture is provided from the first gas source 428, and a second process gas mixture is provided from the second gas source 429.

In one embodiment of the present invention, a microcrystalline silicon layer may be deposited on a substrate, such as the intrinsic type microcrystalline silicon layer 134 shown in FIG. 1B. In one embodiment, the first process gas mixture comprises a ratio of silicon-based gas to hydrogen gas of between about 1:90 to about 1:110, such as about 1:100. In one embodiment, the second process gas mixture comprises a ratio of silicon-based gas to hydrogen gas of between about 1:115 to about 1:125, such as about 1:120. Therefore, the ratio of precursor gases in the process gas may be optimized to provide improved deposition uniformity across a substrate disposed in the process chamber 400.

In another embodiment, the process chamber 400 may be used to deposit both amorphous silicon layers and microcrystalline layers on the same substrate for forming a solar cell, such as solar cell 100 depicted in FIG. 1B. For instance, process gas from the first gas source 428 may be supplied through the central region 421 of the backing plate 420 for forming an amorphous silicon layer on a substrate disposed in the process chamber 400 in one process step, such as forming the intrinsic type amorphous silicon layer 124 for the solar cell 100 depicted in FIG. 1B. Subsequently, process gas from the second gas source 429 may be supplied through the plurality of corner regions 422 of the backing plate 420 for forming a microcrystalline silicon layer on the substrate disposed in the process chamber 400, such as forming the intrinsic type microcrystalline silicon layer 134 shown in FIG. 1B.

In one embodiment, the first process gas from the first gas source may be delivered to the central region 421 of the backing plate 420 at a first flow rate. Additionally, the second process gas may be delivered to the corner regions 422 at a second flow rate. Therefore, the ratio of the flow rate of process gas delivered to the central region 421 to the flow rate of process gas delivered to the corner regions may be optimized to provide improved deposition uniformity across a substrate disposed in the process chamber 400.

In one embodiment, the process gas may be delivered to each of the corner regions 422 at a different flow rate. Therefore, the ratio of the flow rate of the process gas delivered through the central region 421 to the ratio of process gas delivered through each corner region 422 may be optimized to provide improved deposition uniformity across a substrate disposed in the process chamber 400.

Although the corner regions 422 are depicted as being in the corners of the backing plate 420, one or more corner regions 422 may extend along an edge of the backing plate 420 as well. As such, process gas flow to the edge regions may also be optimized to account for asymmetry in chamber walls, such as slit valve openings.

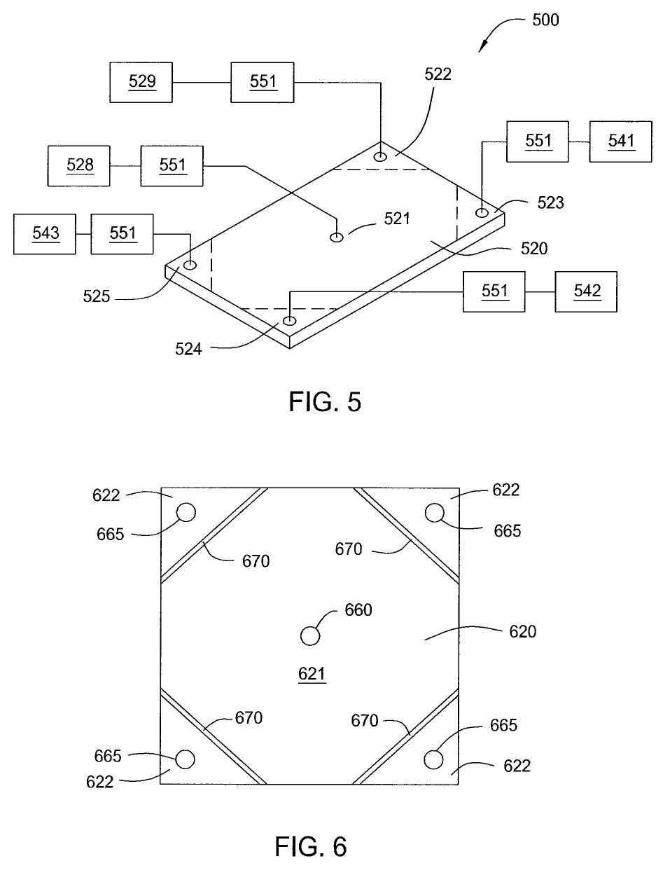

FIG. 5 is a schematic, isometric view of a backing plate 520 of a process chamber 500 according to one embodiment of the present invention. In one embodiment, process gases may be supplied to the process chamber 500 via a plurality of gas sources. Process gas from a first gas source 528 may be supplied through a central region 521 of the backing plate 520. The flow and/or pressure of process gas through the central region 521 of the backing plate 520 may be regulated via a mass flow controller 551.

In one embodiment, process gas from a second gas source 529 may be supplied through a first corner region 522 of the backing plate 520. A process gas from a third gas source 541 may be supplied through a second corner region 523 of the backing plate 520. A process gas from a fourth gas source 542 may be supplied through a third corner region 524 of the backing plate 520. A process gas from a fifth gas source 543 may be supplied through a fourth corner region 525 of the backing plate 520.

In one embodiment, the flow and/or pressure of process gas through the first corner region 522, the second corner region 523, the third corner region 524, and the fourth corner region 525 of the backing plate 520 may each be regulated by a mass flow controller 551.

In one embodiment, the process gas from each of the gas sources 528, 529, 541, 542, and 543 may comprise one or more precursor gases. In one embodiment, a different process gas mixture is supplied from each of the different gas sources 528, 529, 541, 542, and 543.

In one embodiment of the present invention, a microcrystalline silicon layer may be deposited on a substrate, such as the intrinsic type microcrystalline silicon layer 134 shown in FIG. 1B. In one embodiment, a first process gas mixture is supplied by the first gas source 528 and comprises a ratio of silicon-based gas to hydrogen gas of between about 1:90 to about 1:110, such as about 1:100. In one embodiment, a second, third, fourth, and fifth process gas mixture is supplied by the second gas source 529, the third gas source 541, the fourth gas source 542, and the fifth gas source 543, respectively. In one embodiment, each of the second, third, fourth, and fifth gas mixtures comprises a ratio of silicon-based gas to hydrogen gas of between about 1:115 to about 1:125. For instance, the second, third, fourth, and fifth gas mixtures may comprise ratios of silicon-based gas to hydrogen based gas of 1:116, 1:118, 1:122, and 1:124, respectively. Therefore, the ratio of precursor gases in the process gas may be optimized to provide improved deposition uniformity across a substrate disposed in the process chamber 500.

In one embodiment, the first process gas from the first gas source may be delivered to the central region 521 of the backing plate 520 at a first flow rate. Additionally, the second, third, fourth, and fifth process gas may be delivered to the corner regions 522, 523, 524, and 525 at a second flow rate. Therefore, the ratio of the flow rate of process gas supplied to the central region 521 to the flow rate of process gas supplied to the corner regions 522, 523, 524, and 525 may be optimized to provide improved deposition uniformity across a substrate disposed in the process chamber 500.

In one embodiment, the process gas may be delivered to each of the corner regions 522, 523, 524, and 525 at a different flow rate. Therefore, the ratio of the flow rate of process gas through the central region 521 to the flow rate of process gas through each corner region 522, 523, 524, and 525 may be optimized to provide improved deposition uniformity across a substrate disposed in the process chamber 500.

Although the corner regions 522, 523, 524, and 525 are depicted as being in the corners of the backing plate 520, one or more of the corner regions 522, 523, 524, and 525 may extend along an edge of the backing plate 520 as well. As such, process gas flow to the edge regions may also be optimized to account for asymmetry in chamber walls, such as slit valve openings.

FIG. 6 is a schematic, bottom view of a backing plate 620 according to one embodiment of the present invention. The backing plate 620 may have a central orifice 660 formed through the backing plate in a central region 621. The central orifice 660 may be coupled to a gas supply, such as the gas source 328, 428, or 528. Additionally, the backing plate 620 may have a corner orifice 665 formed through the backing plate in each corner region 622. In one embodiment, each corner orifice 665 may be coupled to a single gas supply, such as the gas source 328 or 429. In one embodiment, each corner orifice 665 may be coupled to a different gas supply, such as the gas source 529, 541, 542, and 543. As previously set forth, this configuration allows different gas mixtures to be introduced into the central region 621 than the corner regions 622. Additionally, this configuration allows the gas mixtures to be introduced into the central region 621 at a different flow rate and/or pressure than the corner regions 622.

In one embodiment, a barrier 670 is provided between the central region 621 and each of the corner regions 622 to provide separate plenums in each of the respective regions between the backing plate 620 and a showerhead disposed thereunder. In one embodiment, the barrier 670 is attached to the backing plate 620 and extending toward the showerhead situated below the backing plate 620. In one embodiment, the barrier 670 is attached to or in contact with the showerhead situated below the backing plate 620. In another embodiment, the barrier 670 extends just short of the showerhead situated below the backing plate 620. These configurations ensure that the gas mixtures provided into the corner regions 622 diffuse through the showerhead situated below the backing plate 620 without significant mixing with the gas mixture provided into the central region 621. Thus, the desired gas mixtures delivered to the corner regions 621 control the deposition to the corner regions of a substrate disposed below the showerhead resulting in improved deposition uniformity and control across the surface of the substrate.

In the embodiments described with respect to FIGS. 3, 4, and 5, the gas mixtures supplied from the gas sources 328, 428, 429, 528, 529, 541, 542, 543, and 544 are presented as a mixture of a silicon-based gas and hydrogen gas. In such embodiments, the silicon-based gas may include monosilane (SiH₄), disilane (Si2H₆), dichlorosilane (SiH₂Cl₂), silicon tetrafluoride (SiF₄), silicon tetrachloride (SiCl₄), and the like. Additionally, the gas mixtures may contain additional gases, such as carrier gases or dopants. In one embodiment, the gas mixtures may comprise a silicon-based gas, hydrogen gas, and either a p-type dopant or an n-type dopant. Suitable p-type dopants include boron-containing sources, such as trimethylboron (TMB (or B(CH₃)₃)), diborane (B₂H₆), boron trifluoride (BF₃), and the like. Suitable n-type dopants include phosphorous-containing sources, such as phosphine and similar compounds. In other embodiments, the gas mixtures may comprise other gases as necessary to deposit the desired films on a substrate disposed in the process chamber.

While the foregoing is directed to embodiments of the present invention, other and further embodiments of the invention may be devised without departing from the basic scope thereof, and the scope thereof is determined by the claims that follow.

1. A processing apparatus, comprising:
a showerhead;
a backing plate positioned adjacent the showerhead such that a plenum is formed between the backing plate and the showerhead;
a first gas source in fluid communication with an orifice formed through a central region of the backing plate; and
a second gas source in fluid communication with an orifice formed through a corner region of the backing plate.

2. The processing apparatus of claim 1, wherein the second gas source is in fluid communication with an orifice formed through each corner region of the backing plate.

3. The processing apparatus of claim 2, further comprising a first mass flow controller in fluid communication with the first gas source for controlling the flow of gases through the orifice formed through the central region of the backing plate.

4. The processing apparatus of claim 3, further comprising a second mass flow controller in fluid communication with the second gas source for controlling the flow of gases through the orifice formed through each corner region of the backing plate.

5. The processing apparatus of claim 3, further comprising a plurality of second mass flow controllers, wherein each second mass flow controller is in fluid communication with the second gas source.

6. The processing apparatus of claim 5, wherein the orifice in each corner region of the backing plate has a separate second mass flow controller in fluid communication therewith.

7. The processing apparatus of claim 2, wherein the plenum is separated into a central region and a plurality of corner regions.

8. The processing apparatus of claim 7, further comprising a barrier disposed between the central region of the plenum and each corner region of the plenum.

9. The processing apparatus of claim 8, wherein each barrier is attached to the backing plate.

10. A processing apparatus, comprising:
a showerhead;
a backing plate positioned adjacent the showerhead such that a plenum is formed between the backing plate and the showerhead, wherein the plenum includes a central region and a plurality of corner regions;
a first gas source in fluid communication with the central region of the plenum;
a first mass flow controller in fluid communication with the first gas source and the central region of the plenum;
a second gas source in fluid communication with at least one corner region of the plenum; and
a second mass flow controller in fluid communication with the second gas source and the at least one corner region of the plenum.

11. The processing apparatus of claim 10, further comprising a barrier disposed between the central region of the plenum and each corner region of the plenum.

12. The processing apparatus of claim 11, further comprising a plurality of mass flow controllers, wherein each corner region of the plenum has a second mass flow controller in fluid communication therewith.

13. The processing apparatus of claim 11, further comprising a plurality of second gas sources, wherein each corner region of the plenum has a second gas source in communication therewith.

14. The processing apparatus of claim 13, further comprising a plurality of mass flow controllers, wherein each corner region of the plenum has a second mass flow controller in fluid communication therewith.

15. A processing apparatus, comprising:
a showerhead;
a backing plate juxtaposed the showerhead such that a plenum is formed between the backing plate and the showerhead, wherein the plenum includes a central region and a plurality of corner regions;
a gas source in fluid communication with the central and corner regions of the plenum;
a first mass flow controller in fluid communication with the gas source and the central region of the plenum; and
a second mass flow controller in fluid communication with the gas source and at least one of the corner regions of the plenum.

16. The processing apparatus of claim 15, further comprising a barrier disposed between the central region of the plenum and each corner region of the plenum.

17. The processing apparatus of claim 16, wherein the barrier is attached to the backing plate.

18. The processing apparatus of claim 16, wherein the second mass flow controller is in fluid communication with each of the corner regions of the plenum.

19. The processing apparatus of claim 16, further comprising a plurality of second mass flow controllers, wherein each corner region of the plenum is in fluid communication with one of the second mass flow controllers.

20. A method for depositing thin films, comprising:
introducing a first gas mixture into a central region of a plenum formed between a backing plate and a showerhead of a processing apparatus;
introducing a second gas mixture into a corner region of the plenum; and
substantially preventing the first gas mixture from mixing with the second gas mixture prior to diffusing through the showerhead.

21. The method of claim 20, wherein the first gas mixture comprises a ratio of silicon-based gas to hydrogen gas between about 1:90 and about 1:110.

22. The method of claim 21, wherein the second gas mixture comprises a ratio of silicon-based gas to hydrogen gas between about 1:115 and about 1:125.

23. The method of claim 22, wherein the silicon-based gas is selected from the group consisting of monosilane, disilane, and dichlorosilane.

24. The method of claim 23, wherein the second gas mixture is introduced into each corner region of the plenum.

25. The method of claim 20, further comprising introducing a third gas mixture into a second corner region of the plenum.
